(19) United States
(12) Patent Application Publication
(10) Pub. No.: US 2007/0297142 A1
(43) Pub. Date: Dec. 27, 2007

(54) POWER SUPPLY APPARATUS HAVING PASSIVE HEAT-DISSIPATION MECHANISM AND FABRICATION METHOD THEREOF

(75) Inventor: Jui-Yuan Hsu, Taoyuan Hsien (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan Hsien (TW)

(21) Appl. No.: 11/467,384

(22) Filed: Aug. 25, 2006

(30) Foreign Application Priority Data
Jun. 21, 2006 (TW) 095122354

(51) Int. Cl. H05K 7/20

(52) U.S. Cl. 361/714

(57) ABSTRACT

A power supply apparatus includes an insulating housing, a printed circuit board and at least an electronic component. The insulating housing has a substantially closed receptacle and made of a material having a thermal conductivity in a range of from 2.0 to 10.0 W/mK. The printed circuit board is accommodated within the receptacle of the insulating housing. The electronic component is mounted on the printed circuit board.

### FIELD OF THE INVENTION

The present invention relates to a power supply apparatus, and more particularly to a power supply apparatus having a passive heat-dissipation mechanism. The present invention also relates to a method for fabricating such a power supply apparatus.

### BACKGROUND OF THE INVENTION

Many electronic products such as notebook computers, personal digital assistant (PDAs), mobile phones and game consoles become essential information, communication or amusement in our daily lives. Usually, the user may simply plug a power supply apparatus into an AC wall outlet commonly found in most homes or offices so as to receive an AC voltage. The power supply apparatus will convert the AC voltage into a regulated DC output voltage for powering the electronic device and/or charging a battery built-in the electronic device.

Take a power adapter for example. The power adapter is electrically interconnected between an electronic product and an external power source. The AC voltage transmitted from the external power source is converted by the circuitry of a printed circuit board inside the power adapter into a regulated DC output voltage for powering the electronic device and/or charging a battery built-in the electronic device. When the power adapter operates, the electronic components on the printed circuit board thereof may generate energy in the form of heat, which is readily accumulated around the printed circuit board and difficult to dissipate away. If the power adapter fails to transfer enough heat to the ambient air, the elevated operating temperature may result in damage of the electronic components, a breakdown of the whole power adapter or reduced power conversion efficiency. Therefore, it is important to dissipate the heat generated from the electronic components to increase the power conversion efficiency.

For most power adapters, there are two mechanisms for dissipating heat, i.e. an active heat-dissipation mechanism and a passive heat-dissipation mechanism. The active heat-dissipation mechanism uses an external driving device (e.g. a fan) or a cooling medium (e.g. a coolant or water) to remove heat generated from the power adapter to the ambient air. The passive heat-dissipation mechanism removes the heat generated from the power adapter to the ambient air via natural convention, radiation or conduction. Since the power adapter is developed toward minimization and high power, the electronic components mounted on the printed circuit board of this power adapter may generate more heat. If the power adapter fails to transfer enough heat to the ambient air, the elevated operating temperature may result in damage of the electronic components, a breakdown of the whole power adapter or reduced power conversion efficiency. Usually, the housing of the conventional power adapter is made plastic material. As known, plastic material has excellent electrical insulation, but low thermal conductivity (e.g. approximately 0.03 W/mK). Due to the low thermal conductivity, the heat accumulated inside the housing is difficult to dissipate away and thus the power conversion efficiency is not satisfied.

Moreover, for preventing damage from high temperature, the housing of the power adapter or some electronic components inside the housing may be made of high-temperature resistant material. The high-temperature resistant material, however, is not cost-effective. Therefore, it is required to provide a heat-dissipation mechanism for increasing heat-dissipation efficiency and power conversion efficiency by selecting the electronic components capable withstanding a relatively lower temperature.

### SUMMARY OF THE INVENTION

It is an object of the present invention to provide a power supply apparatus having a passive heat-dissipation mechanism for increasing heat-dissipation efficiency and power conversion efficiency by selecting a desired thermal conductivity range of the insulating housing thereof.

It is another object of the present invention to provide a process for fabricating the power supply apparatus by using a lookup table and selecting a desired thermal conductivity range of the insulating housing, thereby increasing heat-dissipation efficiency and power conversion efficiency.

In accordance with a first aspect of the present invention, there is provided a power supply apparatus having a passive heat-dissipation mechanism. The power supply apparatus comprises an insulating housing, a printed circuit board and at least an electronic component. The insulating housing has a substantially closed receptacle and made of a material having a thermal conductivity in a range of from 2.0 to 10.0 W/mK. The printed circuit board is accommodated within the receptacle of the insulating housing. The electronic component is mounted on the printed circuit board.

In accordance with a second aspect of the present invention, there is provided a process for fabricating a power supply apparatus having a passive heat-dissipation mechanism. The process comprises steps of providing an insulating housing having a substantially closed receptacle and made of a material having a thermal conductivity in a range of from 2.0 to 10.0 W/mK, providing a printed circuit board having at least an electronic component mounted thereon, and accommodating the printed circuit board within the receptacle of the insulating housing, thereby fabricating the power supply apparatus.

In accordance with a third aspect of the present invention, there is provided a process for fabricating a power supply apparatus having a passive heat-dissipation mechanism. The process comprises steps of providing a lookup table indicating the thermal conductivities of an insulating housing versus the average temperatures at the surfaces of the insulating housing and/or the thermal conductivities of the insulating housing versus the average temperatures of electronic components inside the insulating housing, selecting a desired thermal conductivity range according to the lookup table, providing an insulating housing having a substantially closed receptacle and made of a material having the desired thermal conductivity range, providing a printed circuit board having at least an electronic component mounted thereon, and accommodating the printed circuit board within the receptacle of the insulating housing, thereby fabricating the power supply apparatus.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic view of a power supply apparatus having a passive heat-dissipation mechanism according to a preferred embodiment of the present invention;

FIG. 2 is a plot illustrating the relationship between the thermal conductivities of the insulating housing and the average temperatures of the electronic components;

FIG. 3 is a plot illustrating the relationship between the thermal conductivities of the insulating housing and the average temperatures at the surfaces of the insulating housing; and

FIG. 4 is a flowchart illustrating the process of fabricating a power adapter having a passive heat-dissipation mechanism according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

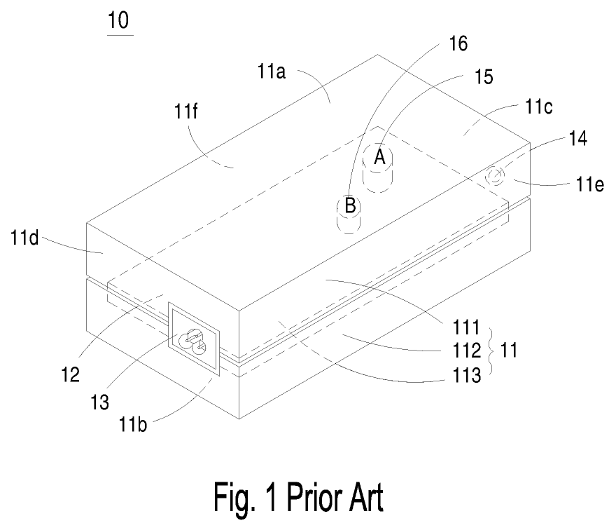

Referring to FIG. 1, a schematic view of a power supply apparatus having a passive heat-dissipation mechanism according to a preferred embodiment of the present invention is illustrated. In this embodiment, an exemplary power supply apparatus is a power adapter 10. The power adapter 10 comprises an insulating housing 11, a printed circuit board 12, a power input member 13 and a power output member 14. The insulating housing 11 is composed of an upper cover 111 and a lower cover 112. A receptacle 113 is defined between the upper cover 111 and the lower cover 112 for accommodating the printed circuit board 12. In this embedment, the insulating housing 11 is substantially a rectangular housing, and includes a first surface 11a, a second surface 11b, a third surface 11c, a fourth surface 11d, a fifth surface 11e and a sixth surface 11f. There are several electronic components mounted on the printed circuit board 12 to provide power conversion. For clarification, only two electronic components 15 and 16 are shown in this drawing. The power input member 13 and the power output member 14 are disposed on opposite sides of the insulating housing 11, and are electrically connected to the printed circuit board 12 (not shown). Via the power input member 13 and the power output member 14, the external power source and the electronic product are respectively connected to the power adapter 10. An AC voltage transmitted from the external power source is converted by the circuitry of a printed circuit board 12 inside the power adapter 10 into a regulated DC output voltage for powering the electronic product. During power conversion, the electronic components 15 and 16 on the printed circuit board 12 may generate energy in the form of heat, and thus the surface A of the electronic component 15 and the surface B of the electronic component 16 are warmed up.

In this embodiment, the insulating housing 11 is made of a material having a higher thermal conductivity than the plastic material. For example, the insulating housing 11 has a thermal conductivity in a range of from 2.0 to 10.0 W/mK. The passive heat-dissipation mechanism of the power adapter 10 is effective to remove the heat generated from the power adapter to the ambient air via natural convention, radiation or conduction. In other words, the heat generated from the electronic components 15 and 16 is transferred to the ambient air through the receptacle 113 and the insulating housing 11 via natural convention, radiation or conduction. Since the insulating housing 11 has a higher thermal conductivity, the heat generated from the electronic components 15 and 16 can be quickly dissipated away to the ambient air. As a consequence, the heat-dissipation efficiency and the power conversion efficiency of the power adapter 10 are enhanced.

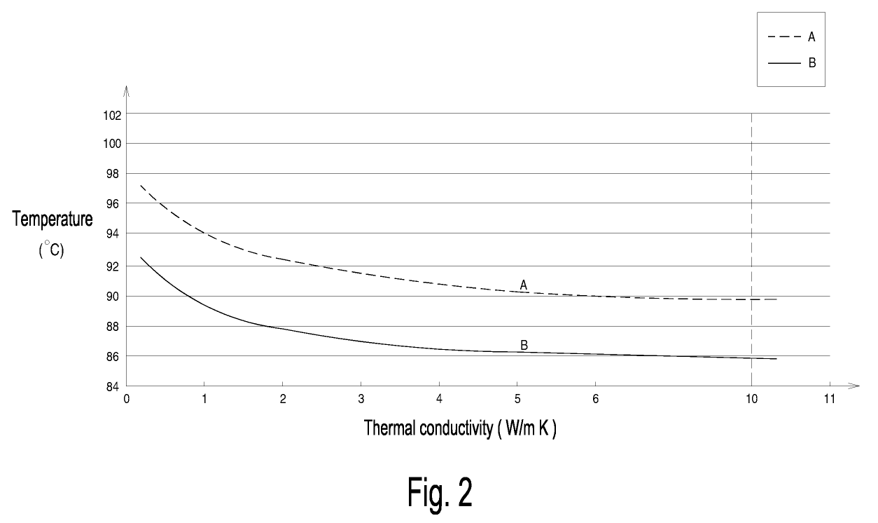

Next, several power adapters having the insulating housings with different thermal conductivities are fabricated with the proviso that the operating power of the power adapter, the electronic components and the operating conditions are identical. During operation of these power adapters, the average temperatures at the surfaces of the electronic components 15 and 16 are measured. The thermal conductivities versus the average temperatures of the electronic components 15 and 16 are plotted in FIG. 2. As shown in FIG. 2, when the insulating housing 11 has a thermal conductivity in a range of from 2.0 to 10.0 W/mK, the average temperatures at the surface A of the electronic component 15 and the surface B of the electronic component 16 are considerably lowered. In other words, the heat generated from the electronic components 15 and 16 are effectively dissipated away, and thus the heat-dissipation efficiency and the power conversion efficiency of the power adapter 10 are enhanced.

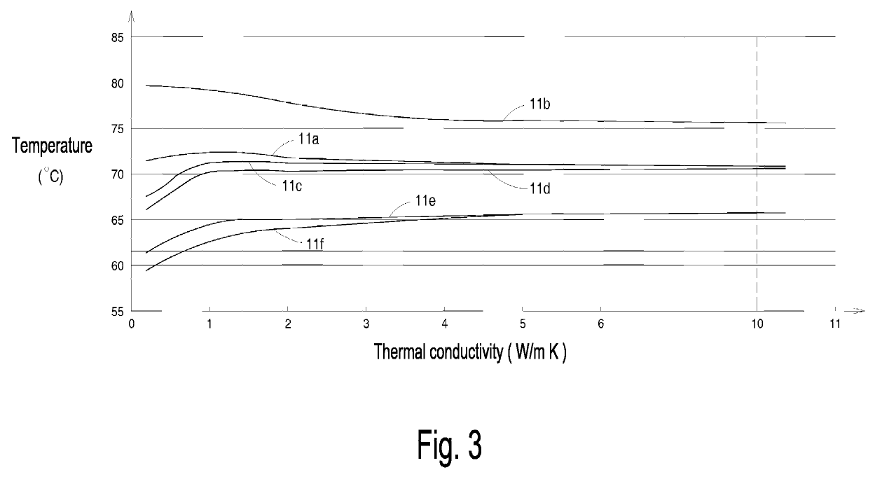

Next, several power adapters having the insulating housings with different thermal conductivities are fabricated with the proviso that the operating power of the power adapter, the electronic components and the operating conditions are identical. During operation of these power adapters, the average temperatures at the surfaces 11a, 11b, 11c, 11d, 11e and 11f of the insulating housing 11 are measured. The thermal conductivities versus the average temperatures of the surfaces 11a, 11b, 11c, 11d, 11e and 11f are plotted in FIG. 3. As shown in FIG. 3, when the insulating housing 11 has a thermal conductivity in a range of from 2.0 to 10.0 W/mK, the average temperatures at the surfaces 11a, 11b, 11c, 11d, 11e and 11f of the insulating housing 11 are considerably lowered. In other words, the heat generated from the electronic components 15 and 16 are effectively dissipated away. As shown in FIG. 3, when the insulating housing 11 has a thermal conductivity in a range of from 2.0 to 10.0 W/mK, the temperature at the surface contacting with the test table (not shown) is lowered, but the temperatures at other surfaces are all increased. That is, the second surface 11b which contacts with the test table has relatively higher thermal resistance, but the other surfaces 11a, 11c, 11d, 11e and 11f have relatively lower thermal resistance. As a consequently, the heat generated from the electronic components 15 and 16 are effectively conducted to the surfaces 11a, 11c, 11d, 11e and 11f and then radiated to the ambient air so as to enhance the heat-dissipation efficiency and the power conversion efficiency of the power adapter 10.

Hereinafter, a process of fabricating a power adapter having a passive heat-dissipation mechanism will be illustrated as follows. First of all, an insulating housing 11 having a closed receptacle 113 is provided, wherein the insulating housing 11 has a thermal conductivity in a range of from 2.0 to 10.0 W/mK. Then, the printed circuit board 12 having the electronic components 15 and 16 mounted thereon is provided. Next, the printed circuit board 12 is accommodated within the receptacle 113 of the insulating housing 11, thereby fabricating the adapter 10 of the present invention. In some embodiments, the insulating housing 11 is made of a composite or a polymeric material having a thermal conductivity in a range of from 2.0 to 10.0 W/mK. Afterward, the power input member 13 and the power output member 14 are electrically connected to the printed circuit board 12.

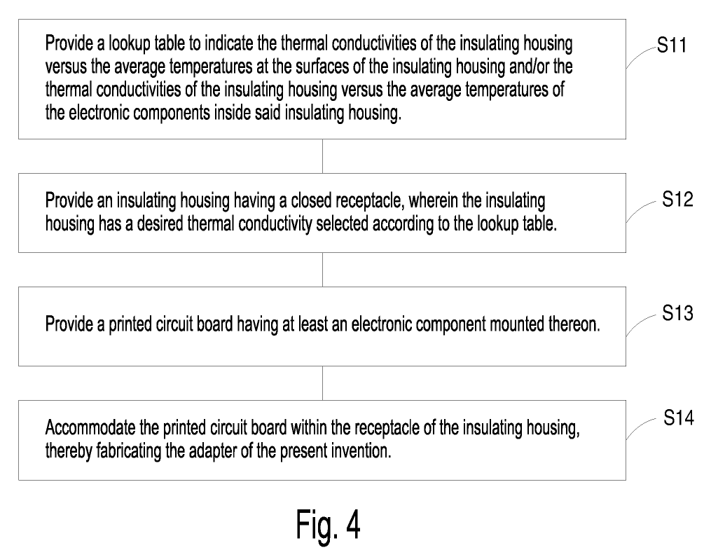

Hereinafter, another process of fabricating a power adapter having a passive heat-dissipation mechanism will be illustrated with reference to the flowchart of FIG. 4. Firstly, a lookup table as shown in FIG. 2 and/or FIG. 3 is illustrated (Step S11) to indicate the thermal conductivities of the insulating housing 11 versus the average temperatures at the surfaces of the insulating housing 11 and/or the thermal conductivities of the insulating housing 11 versus the average temperatures of the electronic components 15 and 16. Then, an insulating housing 11 having a closed receptacle 113 is provided, wherein the insulating housing 11 has a desired thermal conductivity selected according to the lookup table (Step S12). Then, the printed circuit board 12 having the electronic components 15 and 16 mounted thereon is provided (Step S13). Next, the printed circuit board 12 is accommodated within the receptacle 113 of the insulating housing 11, thereby fabricating the power adapter 10 of the present invention (Step S14). In some embodiments, the insulating housing 11 is preferably made of a composite or a polymeric material having a thermal conductivity in a range of from 2.0 to 10.0 W/mK. Afterward, the power input member 13 and the power output member 14 are electrically connected to the printed circuit board 12.

From the above description, the power adapter having a passive heat-dissipation mechanism is capable of enhancing the heat-dissipation efficiency and the power conversion efficiency of the power adapter by selecting the insulating housing having the desired thermal conductivity.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power supply apparatus having a passive heat-dissipation mechanism, said power supply apparatus comprising:
an insulating housing having a substantially closed receptacle and made of a material having a thermal conductivity in a range of from 2.0 to 10.0 W/mK;
a printed circuit board accommodated within said receptacle of said insulating housing; and
at least an electronic component mounted on said printed circuit board.

2. The power supply apparatus according to claim 1 wherein said insulating housing is made of a composite material.

3. The power supply apparatus according to claim 1 wherein said insulating housing is made of a polymeric material.

4. The power supply apparatus according to claim 1 wherein said power supply apparatus is a power adapter.

5. The power supply apparatus according to claim 1 further comprising a power input member and a power output member disposed on opposite sides of said insulating housing and electrically connected to said printed circuit board.

6. A process for fabricating a power supply apparatus having a passive heat-dissipation mechanism, said process comprising steps of:
providing an insulating housing having a substantially closed receptacle and made of a material having a thermal conductivity in a range of from 2.0 to 10.0 W/mK;
providing a printed circuit board having at least an electronic component mounted thereon; and
accommodating said printed circuit board within said receptacle of said insulating housing, thereby fabricating said power supply apparatus.

7. The process according to claim 6 wherein said insulating housing is made of a composite material.

8. The process according to claim 6 wherein said insulating housing is made of a polymeric material.

9. The process according to claim 6 wherein said power supply apparatus is a power adapter.

10. The process according to claim 6 further comprising a step of electrically connecting a power input member and a power output member to said printed circuit board.

11. A process for fabricating a power supply apparatus having a passive heat-dissipation mechanism, said process comprising steps of:
providing a lookup table indicating the thermal conductivities of an insulating housing versus the average temperatures at the surfaces of said insulating housing and/or the thermal conductivities of said insulating housing versus the average temperatures of electronic components inside said insulating housing;
selecting a desired thermal conductivity range according to said lookup table;
providing an insulating housing having a substantially closed receptacle and made of a material having said desired thermal conductivity range;
providing a printed circuit board having at least an electronic component mounted thereon; and
accommodating said printed circuit board within said receptacle of said insulating housing, thereby fabricating said power supply apparatus.

12. The process according to claim 11 wherein said insulating housing is made of a composite material.

13. The process according to claim 11 wherein said insulating housing is made of a polymeric material.

14. The process according to claim 11 wherein said power supply apparatus is a power adapter.

15. The process according to claim 11 wherein said desired thermal conductivity range is from 2.0 to 10.0 W/mK.

16. The process according to claim 11 further comprising a step of electrically connecting a power input member and a power output member to said printed circuit board.
